(19) United States
(12) Patent Application Publication
(10) Pub. No.: US 2025/0107056 A1
(43) Pub. Date: Mar. 27, 2025

(54) POSITIONING STRUCTURE, COMPONENT MOUNTING MACHINE, AND METHOD FOR MANUFACTURING SUBSTRATE

(71) Applicant: FUJI CORPORATION, Chiryu (JP)

(72) Inventor: Norio HOSOI, Chiryu-shi (JP)

(73) Assignee: FUJI CORPORATION, Chiryu (JP)

(21) Appl. No.: 18/727,736

(22) PCT Filed: Feb. 14, 2022
(86) PCT No.: PCT/JP2022/005663

§ 371 Date: Jul. 10, 2024

(51) Int. Cl. H05K 13/04; H05K 13/00

(52) U.S. Cl. CPC H05K 13/0419; H05K 13/0015

(57) ABSTRACT

A positioning structure of the present disclosure is a positioning structure for relatively positioning a first member having a positioning pin and a second member having a positioning hole into which the positioning pin is fitted, in which the positioning pin has a root portion and a tip portion provided separately from the root portion, and the positioning pin is inserted into the positioning hole from the tip portion to relatively position the first member with respect to the second member.

### TECHNICAL FIELD

The present description discloses a positioning structure, a component mounting machine, and a method for manufacturing a board.

### BACKGROUND ART

Conventionally, a positioning structure is known in which a positioning pin formed in a first member is fitted into a positioning hole formed in a second member to position the first member with respect to the second member. For example, Patent Literature 1 discloses a tape feeder positioning structure in which a positioning pin provided on an end surface of a tape feeder is fitted into a positioning hole provided in an electronic component supply section to position the tape feeder with respect to the electronic component supply section.

### PATENT LITERATURE

Patent Literature 1: JP-A-2010-92962

### BRIEF SUMMARY

### Technical Problem

However, when the tape feeder is repeatedly attached to and detached from the electronic component supply section by using the tape feeder for a middle or long period, the positioning pin is worn by friction with a peripheral wall of the positioning hole. When the tape feeder is positioned by fitting the positioning pin into the positioning hole in a state where the positioning pin is worn, the accuracy of the positioning may be reduced.

A main object of the present disclosure is to maintain positioning accuracy of an article for a middle or long period.

### Solution to Problem

A positioning structure of the present disclosure is a positioning structure for relatively positioning a first member having a positioning pin and a second member having a positioning hole into which the positioning pin is fitted,
in which the positioning pin has a root portion and a tip portion provided separately from the root portion,
the first member is relatively positioned with respect to the second member according to insertion into the positioning hole from the tip portion, and
the positioning pin is inserted into the positioning hole from the tip portion to relatively position the first member with respect to the second member.

In this positioning structure, the positioning pin has a root portion and a tip portion provided separately from the root portion. Therefore, the tip portion is exchangeable. Accordingly, even when the positioning pin wears over a middle or long period of use, positioning accuracy can be maintained by exchanging the tip portion.

A component mounting machine of the present disclosure is a component mounting machine for collecting a supplied component by a collecting member and mounting the component on a board, the component mounting machine including:
a tape feeder having a positioning pin in which a root portion and a tip portion are separately provided; and
a feeder setting table having a positioning hole into which the positioning pin is fitted,
wherein the positioning pin is inserted from the tip portion into the positioning hole, thereby positioning the tape feeder relative to the feeder setting table.

This component mounting machine has the same effects as those of the positioning structure described above.

A method for manufacturing a board according to the present disclosure includes:
inserting a positioning pin in which a root portion and a tip portion provided in a tape feeder are separated from each other into a positioning hole provided in a feeder setting table to position the tape feeder in the feeder setting table;
supplying a component from the positioned tape feeder to a component mounting machine main body; and
collecting the supplied component by the component mounting machine main body and mounting the component on the board.

This method for manufacturing a board has the same effect as those of the positioning structure described above.

### BRIEF DESCRIPTION OF DRAWINGS

FIG. 1 is a schematic configuration view of component mounting system 1.

FIG. 2 is a perspective view of tape feeder 20.

FIG. 3 is an enlarged view of a portion A in FIG. 2.

FIG. 4 is a cross-sectional view of tape feeder 20 taken along a YZ plane.

FIG. 5 is a cross-sectional view of root portion 30 taken along the YZ plane.

FIG. 6 is a cross-sectional view of tip portion 31 taken along the YZ plane.

FIG. 7 is a cross-sectional view of first positioning pin 24 taken along the YZ plane.

FIG. 8 is a perspective view of feeder setting table 40.

FIG. 9 is a cross-sectional view of upright wall portion 42 taken along the YZ plane.

FIG. 10A is a view illustrating a state in which tape feeder 20 with respect to feeder setting table 40 is positioned by positioning structure 50.

FIG. 10B is a view illustrating the state in which tape feeder 20 with respect to feeder setting table 40 is positioned by positioning structure 50.

FIG. 10C is a view illustrating the state in which tape feeder 20 with respect to feeder setting table 40 is positioned by positioning structure 50.

### DESCRIPTION OF EMBODIMENTS

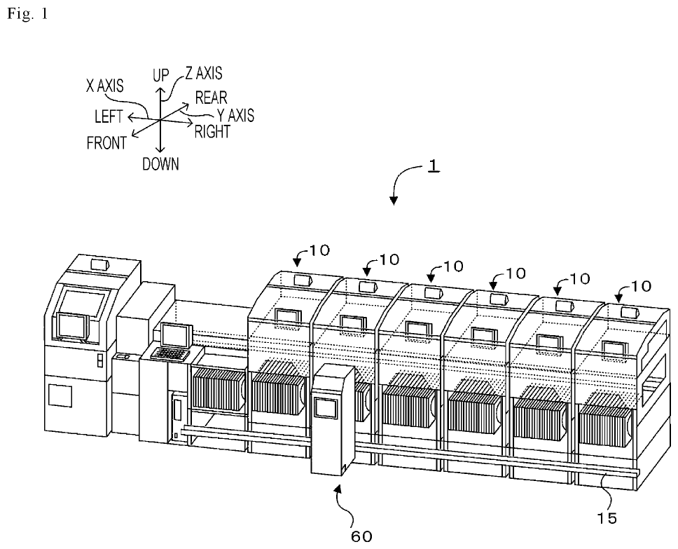

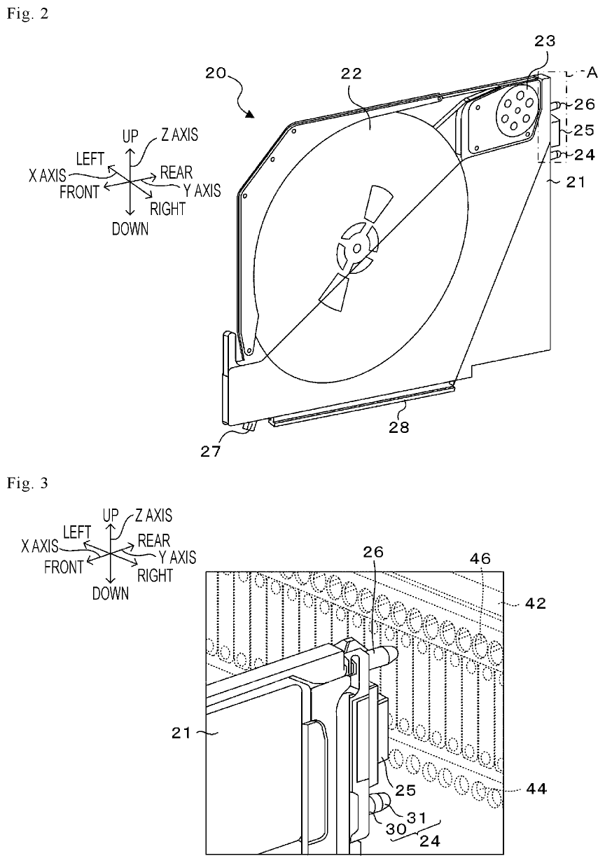

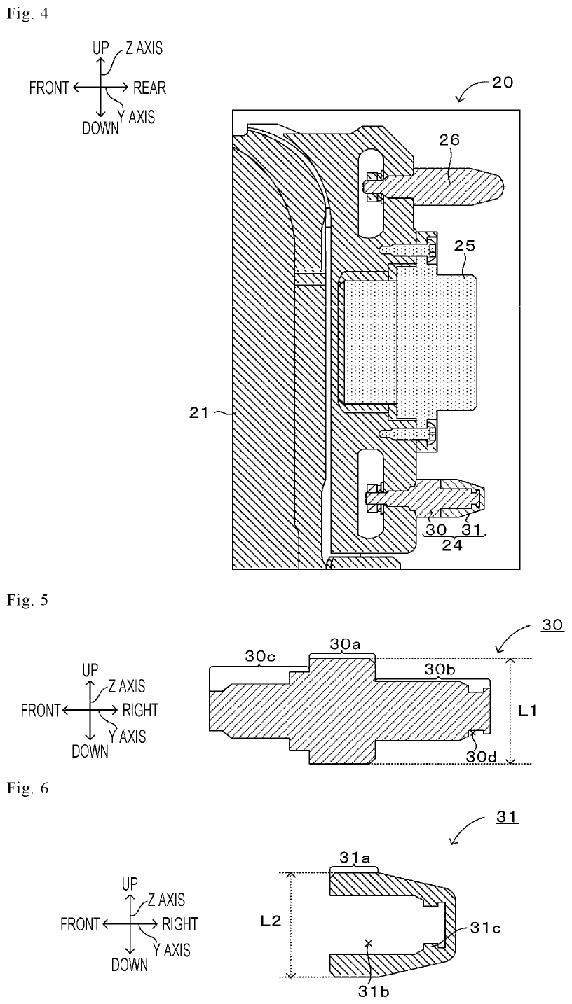

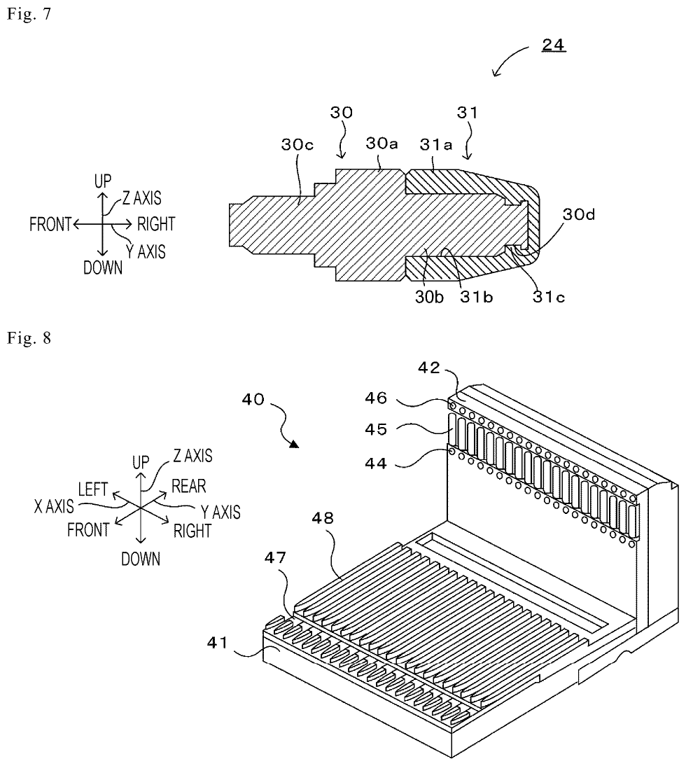

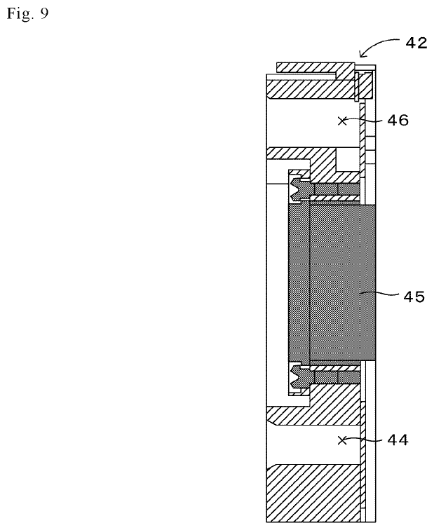

A preferred embodiment of the present disclosure will be described below with reference to the accompanying drawings. FIG. 1 is a schematic configuration view of component mounting system 1. FIG. 2 is a perspective view of tape feeder 20. FIG. 3 is an enlarged view of a portion A in FIG. 2. FIG. 4 is a cross-sectional view of tape feeder 20 taken along a YZ plane. FIG. 5 is a cross-sectional view of root portion 30 taken along the YZ plane. FIG. 6 is a cross-sectional view of tip portion 31 taken along the YZ plane. FIG. 7 is a cross-sectional view of first positioning pin 24 taken along the YZ plane. FIG. 8 is a perspective view of feeder setting table 40. FIG. 9 is a cross-sectional view of upright wall portion 42 taken along the YZ plane. In FIG. 3, upright wall portion 42 is indicated by a broken line for convenience. Here, a left-right direction illustrated in FIGS. 1 to 3 and 8 is an X-axis direction (direction perpendicular to the paper surface in FIGS. 4 to 6 and 9), a front-rear direction illustrated in FIGS. 1 to 9 is a Y-axis direction, and an up-down direction illustrated in FIGS. 1 to 9 is a Z-axis direction.

Component mounting system 1 produces board S on which a component is mounted, and as illustrated in FIG. 1, component mounting system 1 includes multiple component mounting machines 10 arranged along a conveyance direction of board S, loader 60, and a management device that manages the entire component mounting system 1.

Component mounting machine 10 includes tape feeder 20 and a component mounting machine main body in which feeder setting table 40 is provided in a front portion. The component mounting machine main body includes a head capable of holding multiple collecting members, a head moving device that horizontally moves the head, a lifting and lowering device that vertically moves the collecting members with respect to the head, a conveyance device that conveys a board, a control device that controls entire component mounting machine 10, and the like. Component mounting machine 10 collects the component supplied from tape feeder 20 by the collecting member and mounts the component on board S.

As illustrated in FIG. 2, tape feeder 20 includes tape reel 22, tape feeding mechanism 23, first positioning pin 24, second positioning pin 26, connector 25, clamp member 27, and rail member 28. In addition, tape feeder 20 includes a control device that controls entire tape feeder 20. Tape reel 22 and tape feeding mechanism 23 are accommodated in case 21.

A tape is wound on tape reel 22. The tape has multiple recessed portions formed at a predetermined interval along a longitudinal direction. Each recessed portion accommodates a component. The components are protected by a film covering a surface of the tape. Tape feeding mechanism 23 feeds the tape from tape reel 22. Tape feeder 20 drives tape feeding mechanism 23 to feed the tape rearward by a predetermined amount, thereby subsequently supplying the components accommodated in the tape to a component supply position. The film of the component accommodated in the tape is peeled off before the component supply position to be exposed at the component supply position, and the component is collected by the collecting member of component mounting machine 10.

As illustrated in FIGS. 2 and 3, first positioning pin 24 is provided to protrude rearward from the rear surface of case 21. As illustrated in FIGS. 3 and 4, first positioning pin 24 has root portion 30 and tip portion 31. First positioning pin 24 has a separate structure in which root portion 30 and tip portion 31 are separately provided.

Root portion 30 is a metal member, and includes base portion 30a, protruding portion 30b, and fixing portion 30c as illustrated in FIG. 5. Base portion 30a is a substantially columnar portion. Protruding portion 30b is provided to protrude from the rear of base portion 30a. Protruding portion 30b is a columnar portion having a smaller diameter than base portion 30a. Circumferential groove 30d is formed on the outer peripheral surface of protruding portion 30b over one circumference along a circumferential direction. Fixing portion 30c is a portion fixed to case 21.

Tip portion 31 is formed of resin, and as illustrated in FIG. 6, is a cap-like member having base portion 31a and recessed portion 31b fitted into protruding portion 30b of root portion 30. The outer peripheral surface of tip portion 31 is formed in a tapered shape whose diameter decreases toward the tip (rear side). Tip portion 31 is provided with columnar recessed portion 31b fitted into protruding portion 30b of root portion 30. Convex stripe 31c is formed on an inner peripheral wall of recessed portion 31b over one circumference along the circumferential direction. Since tip portion 31 is formed of resin, tip portion 31 can be exchanged with a new one easily even when tip portion 31 is deteriorated by abrasion or the like.

As illustrated in FIG. 7, in first positioning pin 24, recessed portion 31b of tip portion 31 is fitted into protruding portion 30b of root portion 30. When recessed portion 31b of tip portion 31 is fitted into protruding portion 30b of root portion 30, convex stripe 31c formed on the inner peripheral wall of recessed portion 31b is fitted into circumferential groove 30d formed on the outer peripheral wall of protruding portion 30b. Diameter L1 of base portion 30a of root portion 30 is equal to diameter L2 of base portion 31a of tip portion 31. Therefore, when protruding portion 30b is fitted into recessed portion 31b, base portion 30a of root portion 30 and base portion 31a of tip portion 31 are substantially flush with each other.

Second positioning pin 26 is a metal member, and as illustrated in FIGS. 3 and 4, second positioning pin 26 is attached to the rear surface of case 21 above first positioning pin 24. As illustrated in FIG. 4, second positioning pin 26 is longer than first positioning pin 24. Second positioning pin 26 has an integral structure in which the root and the tip are integrally formed. The outer peripheral surface of second positioning pin 26 has an outer diameter similar to that of the first positioning pin, and has a tapered shape whose diameter decreases toward the tip.

As illustrated in FIGS. 2, 3, and 4, connector 25 is provided between first positioning pin 24 and second positioning pin 26. As illustrated in FIG. 2, clamp member 27 is elastically supported to protrude from the lower surface of case 21. Rail member 28 extends rearward of clamp member 27 and has an inverted T-shaped cross section.

Tape feeder 20 is detachably attached to feeder setting table 40 provided in front of component mounting machine 10. As illustrated in FIG. 8, feeder setting table 40 includes support portion 41 that supports tape feeder 20, and upright wall portion 42 that rises vertically from support portion 41.

Support portion 41 has slot 48 into which tape feeder 20 is inserted. Multiple slots 48 are formed in support portion 41 to extend in the front-rear direction and be arranged in the left-right direction. Slot 48 is a groove having a T-shaped cross section. Rail member 28 having an inverted T-shaped cross section provided on the lower surface of tape feeder 20 is inserted into slot 48. Clamp groove 47 is provided in the middle of slot 48. When rail member 28 having an inverted T-shaped cross section of tape feeder 20 is inserted from the front to the rear of slot 48, clamp member 27 provided on the lower surface of tape feeder 20 is fitted into clamp groove 47. Thus, tape feeder 20 is supported by slot 48 in a vertically placed state. Clamp member 27 and clamp groove 47 position tape feeder 20 in the front-rear direction with respect to feeder setting table 40.

As illustrated in FIGS. 8 and 9, upright wall portion 42 includes first positioning hole 44, second positioning hole 46, and connector 45.

As illustrated in FIGS. 8 and 9, first positioning hole 44 is formed in the front surface of upright wall portion 42. First positioning hole 44 is a hole into which first positioning pin 24 of tape feeder 20 is fitted. First positioning hole 44 is a round hole. The peripheral edge of first positioning hole 44 is chamfered as illustrated in FIG. 9. By fitting first positioning pin 24 into first positioning hole 44, tape feeder 20 is positioned in the up-down direction with respect to feeder setting table 40.

As illustrated in FIGS. 8 and 9, second positioning hole 46 is formed above first positioning hole 44 in the front surface of upright wall portion 42. Second positioning hole 46 is a hole into which second positioning pin 26 of tape feeder 20 is fitted. Second positioning hole 46 is an elongated hole extending in a direction of first positioning hole 44 and second positioning hole 46, specifically, in the up-down direction. The diameter of second positioning hole 46 in the left-right direction is set to be slightly larger than the diameter of second positioning pin 26 in the left-right direction. The diameter of second positioning hole 46 in the up-down direction is set to be larger than the diameter of second positioning hole 46 in the left-right direction. The peripheral edge of second positioning hole 46 is chamfered as illustrated in FIG. 9. By fitting second positioning pin 26 into second positioning hole 46, tape feeder 20 in the left-right direction with respect to feeder setting table 40 is positioned. Since second positioning hole 46 is an elongated hole extending in the up-down direction and has a chamfered peripheral edge, second positioning pin 26 can be correctly inserted even when a slight displacement occurs when inserting second positioning pin 26.

In the present embodiment, a structure in which tape feeder 20 in the front-rear direction with respect to feeder setting table 40 is positioned by clamp member 27 and clamp groove 47, tape feeder 20 in the left-right direction with respect to feeder setting table 40 is positioned by first positioning pin 24 and first positioning hole 44, and tape feeder 20 in the up-down direction with respect to feeder setting table 40 is positioned by second positioning pin 26 and second positioning hole 46 is referred to as positioning structure 50.

Connector 45 is provided between first positioning hole 44 and second positioning hole 46 for each slot 48. In a state where rail member 28 of tape feeder 20 is inserted into slot 48 and clamp member 27 is fitted into clamp groove 47, when first positioning pin 24 of tape feeder 20 is fitted into first positioning hole 44, second positioning pin 26 of tape feeder 20 is fitted into second positioning hole 46. Then, connector 25 of tape feeder 20 is connected to connector 45 of feeder setting table 40. Thus, tape feeder 20 and feeder setting table 40 are electrically connected.

As illustrated in FIG. 1, loader 60 is a device that moves the front surface of component mounting machine 10 along guide rail 15 to supply tape feeder 20 to be used to each component mounting machine 10 or to collect used tape feeder 20 from each component mounting machine 10. Loader 60 includes a loader moving device that moves loader 60 along guide rail 15 disposed in front of component mounting machine 10, a feeder transferring device that transfers tape feeder 20 to and from component mounting machine 10, a loader control device that outputs a drive signal to the loader moving device and the feeder transferring device, and the like. The loader control device is connected to the control device of component mounting machine 10 via a network (not illustrated) and exchanges signals.

Next, an operation of component mounting system 1 configured in this way will be described. First, a component mounting process executed by component mounting machine 10 will be described. This process is executed by the control device of component mounting machine 10 after a component mounting start instruction is input from an operator to the control device of component mounting machine 10.

First, the control device of component mounting machine 10 controls the conveyance device such that the board is conveyed to a predetermined position of the conveyance device. Next, the control device of component mounting machine 10 outputs a component supply instruction to the control device of tape feeder 20. When the component supply instruction is input, the control device of tape feeder 20 controls tape feeding mechanism 23 such that the component is supplied to the component supply position. Next, the control device of component mounting machine 10 drives and controls the head, the head moving device, and the lifting and lowering device of component mounting machine 10 such that the component supplied by tape feeder 20 is collected by the collecting member and mounted on board S. Then, the control device of component mounting machine 10 controls the conveyance device such that the board is conveyed to the downstream side after all the components to be mounted in the own device are mounted on board S. The control device of component mounting machine 10 ends the component mounting process after manufacturing a planned number of boards by the own device.

Next, a feeder exchange process for exchanging tape feeder 20 set to feeder setting table 40 with tape feeder 20 held by loader 60 will be described. This process is executed by the loader control device of loader 60 after a feeder exchange request is input from the control device of component mounting machine 10 or the management device of component mounting system 1. The feeder exchange request is output from the control device of component mounting machine 10 to the loader control device via the management device of component mounting system 1 in a case where the number of remaining components accommodated in tape feeder 20 set to feeder setting table 40 of component mounting machine 10 becomes small and the component shortage is predicted. Further, when the type of the board manufactured by component mounting machine 10 is changed, the feeder exchange request is output from the management device of component mounting system 1 to the loader control device. When the feeder exchange request is input, loader 60 holds tape feeder 20 (tape feeder 20 accommodating the component to be used) which is an exchange target.

When this process is started, the control device of loader 60 first drives and controls the loader moving device so that loader 60 moves to the front of component mounting machine 10 that has output a feeder replenishment request. Subsequently, the loader control device controls the feeder transferring device such that the used tape feeder 20 is collected from component mounting machine 10. Next, the control device of loader 60 drives and controls the feeder transferring device such that tape feeder 20 which is the exchange target is fed and set to feeder setting table 40.

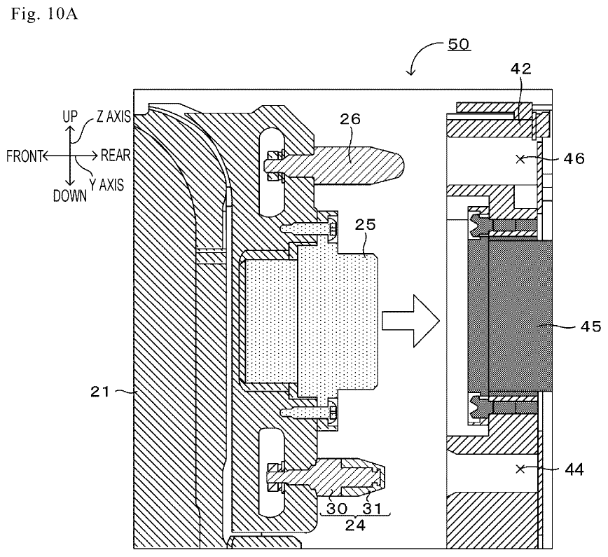

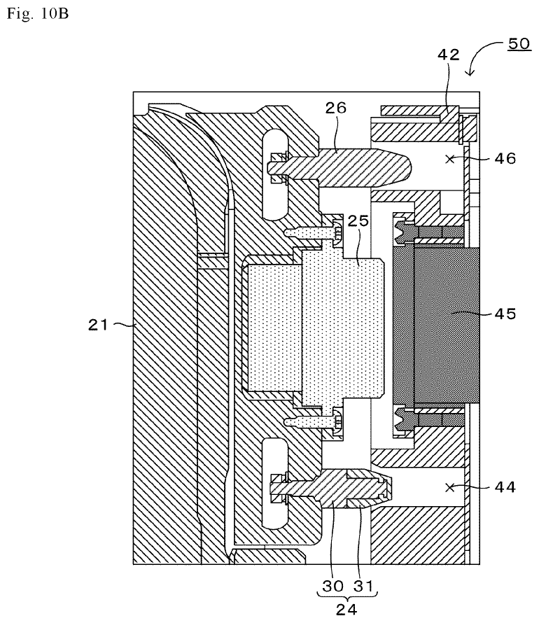

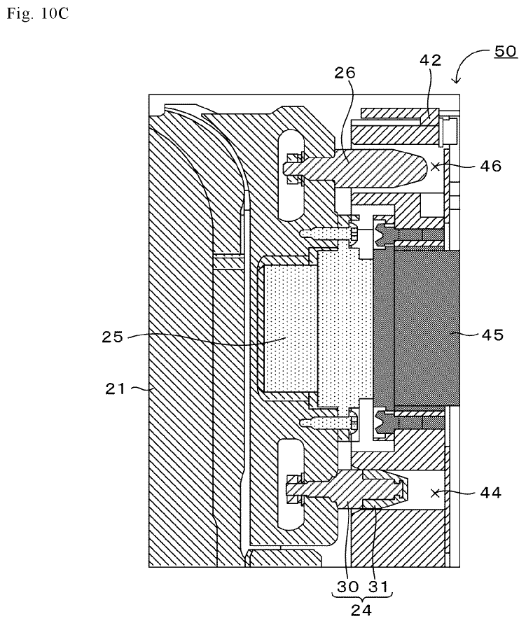

At this time, how tape feeder 20 with respect to feeder setting table 40 is positioned will be described with reference to FIGS. 10A to 10C. FIGS. 10A to 10C are views illustrating a state in which tape feeder 20 with respect to feeder setting table 40 is positioned by positioning structure 50.

First, when rail member 28 of tape feeder 20 starts to be inserted into slot 48 of feeder setting table 40, the position of first positioning pin 24 in the up-down direction and the position of second positioning pin 26 in the up-down direction become the following positions. That is, the position of first positioning pin 24 in the up-down direction is slightly lower than first positioning hole 44, and the position of second positioning pin 26 in the up-down direction is included in second positioning hole 46 in the up-down direction. The reason why second positioning pin 26 is included in second positioning hole 46 in the up-down direction is that second positioning hole 46 is an elongated hole extending in the up-down direction.

When tape feeder 20 is pushed rearward, as illustrated in FIG. 10B, second positioning pin 26 is fitted into second positioning hole 46 before first positioning pin 24 is fitted into first positioning hole 44. This is because second positioning pin 26 is longer than first positioning pin 24. Thus, tape feeder 20 in the left-right direction with respect to feeder setting table 40 is positioned.

When tape feeder 20 is further pushed rearward from the state illustrated in FIG. 10B, the outer peripheral surface of tapered tip portion 31 of first positioning pin 24 rides on the portion having the chamfered peripheral edge of the peripheral wall of first positioning hole 44. Then, as illustrated in FIG. 10C, base portion 30a of root portion 30 and base portion 31a of tip portion 31 of first positioning pin 24 are fitted into first positioning hole 44. At this time, tape feeder 20 is lifted slightly upward together with first positioning pin 24. Thus, tape feeder 20 in the up-down direction with respect to feeder setting table 40 is positioned.

When tape feeder 20 is further pushed rearward and clamp member 27 is fitted into clamp groove 47, tape feeder 20 in the front-rear direction with respect to feeder setting table 40 is positioned.

After confirming that tape feeder 20 to be used is set to feeder setting table 40, the loader control device ends the feeder exchange process.

Here, a correspondence relationship between elements of the present embodiment will be described. That is, tape feeder 20 of the present embodiment corresponds to a first member of the present disclosure, feeder setting table 40 corresponds to a second member, first positioning pin 24 corresponds to a first positioning pin, second positioning pin 26 corresponds to a second positioning pin, first positioning hole 44 corresponds to a first positioning hole, and second positioning hole 46 corresponds to a second positioning hole.

In positioning structure 50 described in detail above, first positioning pin 24 includes root portion 30 and tip portion 31 provided separately from root portion 30. Therefore, tip portion 31 is exchangeable. Accordingly, even when first positioning pin 24 wears over a middle or long period of use, the positioning accuracy can be maintained by exchanging tip portion 31.

In positioning structure 50, root portion 30 is formed of metal, and tip portion 31 is formed of resin. Therefore, the positioning accuracy can be ensured, and tip portion 31 is less likely to wear out. This is because root portion 30 is less likely to be deformed, and tip portion 31 has good slidability. Further, root portion 30 has protruding portion 30b, tip portion 31 has recessed portion 31b to be fitted into protruding portion 30b, circumferential groove 30d is formed on the outer peripheral surface of protruding portion 30b, and convex stripe 31d to be fitted into circumferential groove 30d when protruding portion 30b and recessed portion 31b are fitted into each other is formed on the inner peripheral surface of recessed portion 31b. Therefore, tip portion 31 is unlikely to come off from root portion 30.

1. A positioning structure for relatively positioning a first member having a positioning pin and a second member having a positioning hole into which the positioning pin is fitted,
wherein the positioning pin has a root portion and a tip portion provided separately from the root portion, and
the positioning pin is inserted into the positioning hole from the tip portion to relatively position the first member with respect to the second member.

2. The positioning structure according to claim 1,
wherein the root portion is formed of metal or resin, and
the tip portion is formed of resin.

3. The positioning structure according to claim 2,
wherein the root portion has a protruding portion,
the tip portion has a recessed portion or a hole fitted into the protruding portion,
a circumferential groove is formed on a first one of an outer peripheral surface of the protruding portion and an inner peripheral surface of the recessed portion, and
a convex stripe fitted into the circumferential groove when the protruding portion and the recessed portion or the hole are fitted into each other is formed on a second one of the outer peripheral surface of the protruding portion and the inner peripheral surface of the recessed portion.

4. The positioning structure according to claim 1,
wherein the first member has, as the positioning pin, a first positioning pin and a second positioning pin arranged in a predetermined direction,
the second member has, as the positioning hole, a first positioning hole into which the first positioning pin is fitted and a second positioning hole into which the second positioning pin is fitted,
the first positioning pin has a separate structure in which the root portion and the tip portion are separately provided,
the second positioning pin has a length longer than that of the second positioning pin and has an integral structure integrally formed from a root to a tip,
the first positioning hole is a round hole, and
the second positioning hole is an elongated hole extending in an arrangement direction of the first positioning hole and the second positioning hole.

5. The positioning structure according to claim 1,
wherein the tip portion is formed in a tapered shape whose diameter decreases toward the tip.

6. A component mounting machine for collecting a supplied component by a collecting member and mounting the component on a board, the component mounting machine comprising:
a tape feeder having a positioning pin in which a root portion and a tip portion are separately provided; and
a feeder setting table having a positioning hole into which the positioning pin is fitted,
wherein the positioning pin is inserted from the tip portion into the positioning hole, thereby positioning the tape feeder relative to the feeder setting table.

7. A method for manufacturing a board, the method comprising:
inserting a positioning pin in which a root portion and a tip portion provided in a tape feeder are separated from each other into a positioning hole provided in a feeder setting table to position the tape feeder in the feeder setting table;
supplying a component from the positioned tape feeder to a component mounting machine main body; and
collecting the supplied component by the component mounting machine main body and mounting the component on the board.
